(19) United States
(12) Patent Application Publication
(10) Pub. No.: US 2021/0202220 A1
(43) Pub. Date: Jul. 1, 2021

(54) INSPECTION METHOD OF PLASMA FORMING SOURCE AND LOAD

(71) Applicant: Tokyo Electron Limited, Tokyo (JP)

(72) Inventor: Shintaro Yawata, Kurokawa-gun (JP)

(21) Appl. No.: 17/126,474

(22) Filed: Dec. 18, 2020

(30) Foreign Application Priority Data
Dec. 25, 2019 (JP) 2019-234411

(51) Int. Cl. H01J 37/32

(52) U.S. Cl. CPC H01J 37/32935; H01J 2237/2007; H01J 37/3211; H01J 37/32091

(57) ABSTRACT

There is provided an inspection method of a plasma forming source. The method includes providing a load configured to be capacitively and inductively coupled to the plasma forming source; and calculating a characteristic of the plasma forming source by receiving a signal from the plasma forming source while sending a reference signal to the plasma forming source.

### CROSS-REFERENCE TO RELATED APPLICATION

This application claims the benefit of Japanese Patent Application No. 2019-234411 filed on Dec. 25, 2019, the entire disclosures of which are incorporated herein by reference.

### TECHNICAL FIELD

The various aspects and embodiments described herein pertain generally to an inspection method for a plasma forming source and a load therefor.

### BACKGROUND

Patent Document 1 describes an impedance matching device. Patent Document 2 describes an imitation load device for inspection of a power source. Patent Document 3 describes an example of a plasma forming source.
Patent Document 1: Japanese Patent Laid-open Publication No. 2004-085446
Patent Document 2: Japanese Laid-open Publication No. 2012-208036
Patent Document 3: Japanese Laid-open Publication No. 2011-119659

### SUMMARY

In one exemplary embodiment, an inspection method of a plasma forming source includes providing a load configured to be capacitively and inductively coupled to the plasma forming source; and calculating a characteristic of the plasma forming source by receiving a signal from the plasma forming source while sending a reference signal to the plasma forming source.

The foregoing summary is illustrative only and is not intended to be any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a diagram illustrating a plasma processing apparatus equipped with a plasma forming source;

FIG. 2 is a diagram for describing an inspection method for the plasma forming source according to an exemplary embodiment;

FIG. 3 is a diagram for describing an inspection method for the plasma forming source according to another exemplary embodiment;

FIG. 4 is a diagram for describing an inspection method for the plasma forming source according to still another exemplary embodiment;

FIG. 5 presents a diagram illustrating a longitudinal sectional structure of the plasma forming source and a load according to the exemplary embodiment;

FIG. 6 is an exploded perspective view of the plasma forming source and the load shown in FIG. 5;

FIG. 7 is a plan view illustrating the load according to the exemplary embodiment;

FIG. 8 is a circuit diagram illustrating an example of a coupling of the plasma forming source and the load; and

FIG. 9 is a plan view illustrating the load according to the exemplary embodiment.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

Hereinafter, various exemplary embodiments will be described.

In one exemplary embodiment, there is provided an inspection method of a plasma forming source. The method includes providing a load configured to be capacitively and inductively coupled to the plasma forming source; and calculating a characteristic of the plasma forming source by receiving a signal from the plasma forming source while sending a reference signal to the plasma forming source.

The load is a dummy load to simulate plasma ideally. Regarding an electric behavior seen from the plasma forming source, this load is assumed to be equivalent to the plasma. If a reference signal (high frequency signal) is applied to the plasma forming source, a reflection signal reflected from the plasma forming source and/or a transmitted signal which has passed through the plasma forming source can be obtained. By receiving the signals from the plasma forming source, it is possible to inspect a characteristic of the plasma forming source in the state the plasma is formed imaginarily.

In the method according to the exemplary embodiment, the load includes a passive element configured to be capacitively and inductively coupled to the plasma forming source; a fixing member configured to fix the passive element to the plasma forming source; and a holding member configured to hold the passive element.

The holding member holds the passive element, and the fixing member fixes the passive element to the plasma forming source. Thus, a position of the passive element is fixed to the plasma forming source, and accurate inspection can be carried out.

In the method according to the exemplary embodiment, the passive element includes an antenna. The antenna may include a capacitor, an inductor and a resistor, and can be capacitively and inductively coupled to the plasma forming source.

In the method according to the exemplary embodiment, the characteristic is a S parameter. The plasma forming source is connected to a network analyzer configured to generate the reference signal and receive the signal from the plasma forming source. The network analyzer is capable of measuring the S parameter (a parameter indicating a relationship between an input signal to the plasma forming source and an output signal from the plasma forming source). If a S parameter of a fine-quality plasma forming source is previously measured, a quality control for an inspection target product can be carried out by measuring a S parameter of a plasma forming source as a target of inspection.

In another exemplary embodiment, a load includes a passive element configured to be capacitively and inductively coupled to a plasma forming source; a fixing member configured to fix the passive element to the plasma forming source; and a holding member configured to hold the passive element. This load can be used for the inspection of the characteristic of the plasma forming source as stated above.

In the load according to another exemplary embodiment, the passive element includes an antenna. As described above, the antenna may include the capacitor, the inductor and the resistor, and can be capacitively and inductively coupled to the plasma forming source. If the plasma forming source includes an antenna, the antenna of the passive element may have the same shape as the antenna of the plasma forming source.

Hereinafter, the various exemplary embodiments will be described in detail with reference to the accompanying drawings. In the various drawings, same or corresponding parts will be assigned same reference numerals, and redundant description will be omitted.

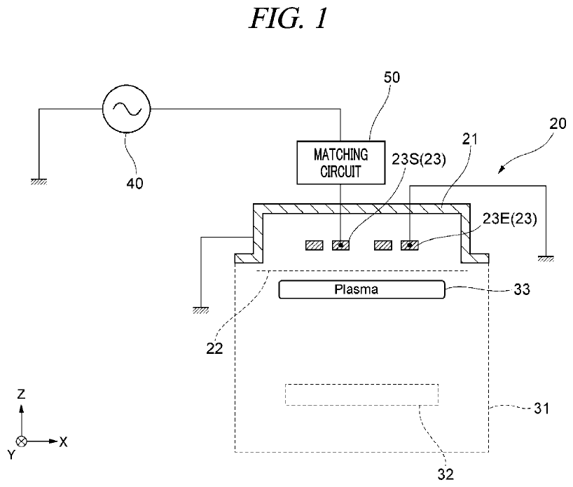

FIG. 1 is a diagram illustrating a plasma processing apparatus equipped with a plasma forming source.

The plasma processing apparatus is equipped with a stage 32 disposed in a processing vessel 31. A substrate as a processing target object is placed on the stage 32. A non-illustrated exhaust device and a non-illustrated gas supply device are connected to the processing vessel 31. A plasma forming source 20 is fixed to a top portion of the processing vessel 31 with a dielectric window 22 therebetween. The dielectric window 22 closes a top opening of the processing vessel 31. The plasma forming source 20 may be of various types. The plasma forming source 20 includes a cylindrical accommodation cover 21 which has an open bottom and is made of a metal. The plasma forming source 20 of the present exemplary embodiment further includes an antenna 23 connected to a non-illustrated supporting member. Plasma 33 is formed under the dielectric window 22 by a high frequency voltage applied to the antenna 23.

When viewed from the top, the antenna 23 may have a spiral shape, a single-ring shape, a multi-ring shape with multiple rings arranged concentrically, a circular shape having multiple slots, or the like. In the present exemplary embodiment, the antenna 23 has a spiral shape, and has a starting point 23S at an inner side and an end point 23E at an outer side.

The dielectric window 22 may be made of an insulator such as alumina Al₂O₃ or a quartz glass. The antenna 23 may be made of a metal such as copper (Cu) or aluminum (Al).

A lower portion of an outer peripheral surface of the accommodation cover 21 has a rib (flange) structure extending in a diametrical direction within a horizontal plane. This rib structure can be fixed to an upper end surface of the processing vessel 31 by using bolts or the like.

The accommodation cover 21 is electrically connected to the ground. The starting point 23S of the antenna 23 is connected to a high frequency power supply 40 via a matching circuit 50. Although the high frequency power supply 40 is generally known to have a frequency of 13.54 MHz, it may have a frequency in a VHF band (30 MHz to 0.3 GHz) or a UHF band, or may have a microwave frequency. In the present exemplary embodiment, the high frequency power supply 40 has a frequency of 13.54 MHz, and a high frequency voltage therefrom is supplied to the antenna 23 by using a coaxial cable.

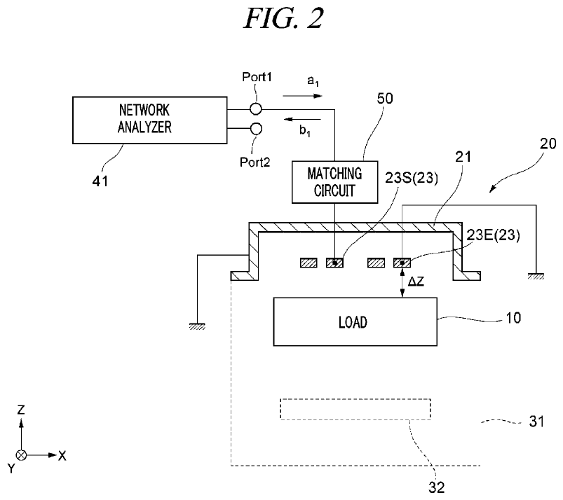

FIG. 2 is a diagram for describing an inspection method for the plasma forming source according to an exemplary embodiment.

When the plasma forming source 20 is inspected, the inspection may be performed in the state that the plasma forming source is mounted in the plasma processing apparatus. In the present exemplary embodiment, however, the plasma forming source 20 is inspected before it is assembled to the plasma processing apparatus. A load 10 is placed directly under the plasma forming source 20 with air therebetween. That is, in performing a measurement according to the present exemplary embodiment, the processing vessel 31 does not exist under the plasma forming source 20. As depicted in FIG. 1, in the state that plasma 33 is formed, the plasma 33 exists under the plasma forming source 20. Since the plasma 33 does not exist when the inspection is performed, the load 10 is used to replace the plasma 33. The load 10 is a dummy load composed of a RLC circuit. Ideally, the load 10 is an equivalent circuit of the plasma 33 in the plasma forming source 20.

The load 10 may not be the perfect equivalent circuit of the plasma 33. To allow the load 10 to serve as the equivalent circuit of the plasma, an antenna having the same shape as the antenna 23 may be used as the load. In this case, though the load is not the perfect equivalent circuit of the plasma 33, it can serve as an inspection load for inspecting a quality of the plasma forming source 20. That is, a characteristic of a fine-quality plasma forming source 20 needs to be previously inspected by a network analyzer 41 in the state that the load 10 is placed, and, then, a characteristic of the plasma forming source 20 as an inspection target object is inspected. If a difference between the measured characteristic (for example, a S parameter) and the characteristic of the fine-quality product is equal to or less than a threshold value (e.g., ±5%), it can be determined that the plasma forming source 20 as the inspection target object is a fine-quality product.

Connection between the individual components is the same as in FIG. 1 except that the network analyzer 41, instead of the first high frequency power supply 40, is electrically connected to the antenna 23. Further, in FIG. 2, though the network analyzer 41 is connected to the antenna 23 via the matching circuit 50, this matching circuit 50 may be removed when the inspection is carried out.

The network analyzer 41 includes a signal source, a reference signal receiver, a reflection signal receiver, a transmitted signal receiver and a display. A reference signal outputted from the signal source is split by a splitter and detected by the reference signal receiver. The reference signal having passed through the splitter is inputted to the plasma forming source 20 (antenna 23), and a reflection signal reflected therefrom is detected by the reflection signal receiver. The transmitted signal having passed through the plasma forming source 20 can be detected by the transmitted signal receiver. A frequency of the reference signal may be equal to a frequency at a time when the plasma is formed.

A reference signal (progressive wave) a₁ is outputted from a first port Port1 of the network analyzer 41 and inputted to the starting point 23S of the antenna 23. The transmitted signal is outputted from the end point 23E of the antenna 23 and flows to the ground. A second port Port2 of the network analyzer 41 is opened. A reflection signal (reflection wave) b₁ reflected from the starting point 23S of the antenna 23 is inputted to the first port Port1 of the network analyzer 41 and detected by the reflection signal receiver.

The network analyzer 41 is capable of detecting the S parameter. The S parameter is defined as b₁=S₁₁×a₁+S₁₂×a₂, b₂=S₂₁×a₁+S₂₂×a₂. Here, b₁ denotes a reflection wave from an object at a first port side; a₁, a progressive wave to the object at the first port side; a₂, a progressive wave to an object at a second port side; and b₂, a reflection wave from the object at the second port side.

To calculate S₁₁=b₁/a₁, the network analyzer 41 operates S₁₁ from the detected reference signal a₁ and reflection signal b₁, and displays an operation result on the display.

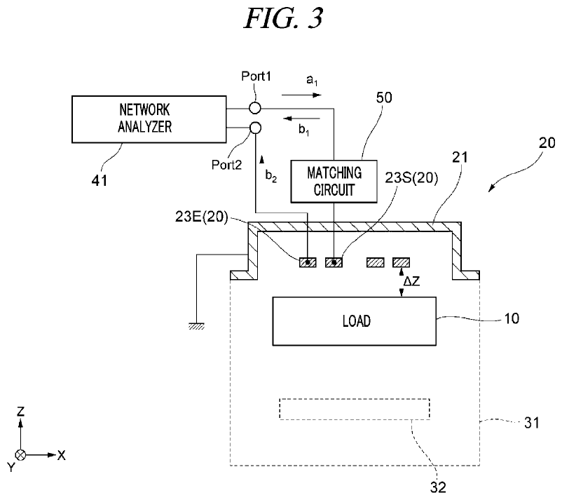

FIG. 3 is a diagram for describing an inspection method for the plasma forming source according to another exemplary embodiment.

A configuration of the present exemplary embodiment is the same as the configuration of FIG. 2 except that the second port Port2 is not opened and connected to the end point 23E of the antenna 23. A method of calculating S₁₁ is the same as described in FIG. 2. Further, to calculate S₂₁=b₂/a₁, the network analyzer 41 operates S₂₁ from the reference signal a₁ detected by the reference signal receiver and the transmitted signal b₂ detected by the transmitted signal receiver, and outputs an operation result on the display.

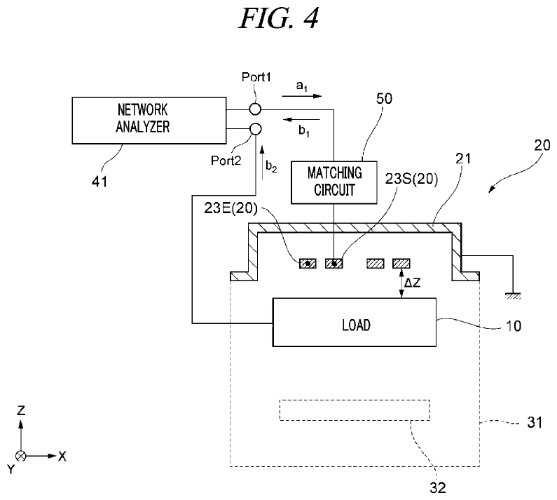

FIG. 4 is a diagram for describing an inspection method for the plasma forming source according to still another exemplary embodiment. A configuration of the present exemplary embodiment is the same as the configuration of FIG. 3 except that the second port Port2 is connected to the load 10 instead of the antenna 23. A high frequency component of the reference signal a₁ reaches the load 10 through an inductive coupling between inductors and a capacitive coupling by a capacitor formed between the antenna 23 and the load 10. The transmitted signal b₂ having passed through the load 10 is inputted to the transmitted signal receiver within the network analyzer 41 via the second port Port2. A method of calculating S₁₁ is the same as described in FIG. 2 and FIG. 3. Further, to calculate S₂₁=b₂/a₁, the network analyzer 41 operates the S₂₁ from the reference signal a₁ detected by the reference signal receiver and the transmitted signal b₂ detected by the transmitted signal detector, and outputs an operation result on the display, the same as in the case of FIG. 3.

In the measurements of FIG. 2 to FIG. 4, though the passive element within the load 10 can be set to be in a floating state, a part of it may be connected to the ground when necessary. Now, a specific example of the load 10 will be explained.

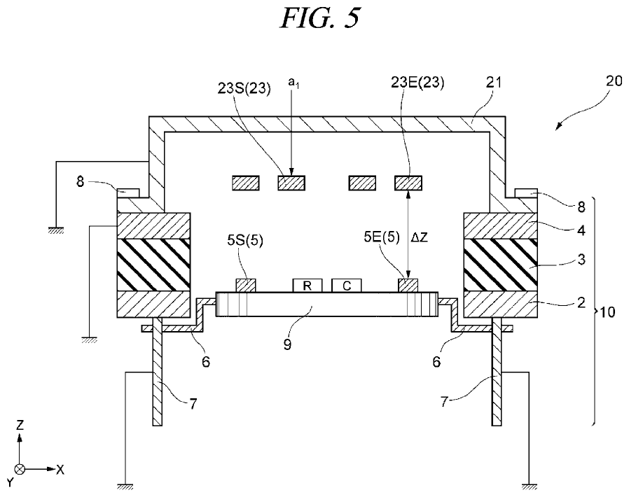

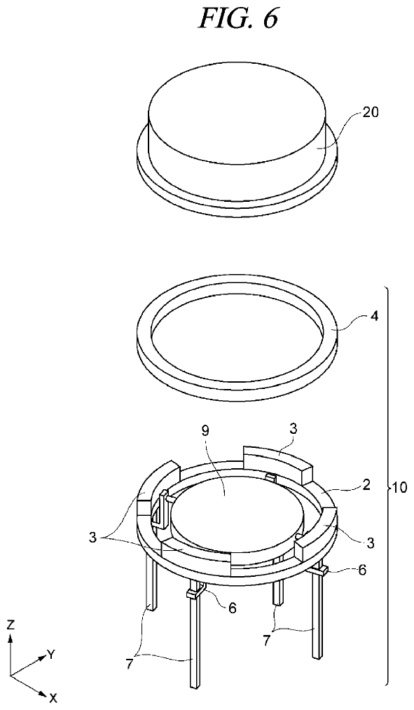

FIG. 5 is a diagram illustrating a longitudinal sectional structure of the plasma forming source and the load according to an exemplary embodiment. FIG. 6 is a perspective view of the plasma forming source and the load shown in FIG. 5. In FIG. 6, illustration of a passive element on a supporting board 9 is omitted.

As illustrated in FIG. 5 and FIG. 6, the load 10 is disposed under plasma forming source 20. The load 10 (jig) includes a circular ring-shaped holding member 2, a plurality of circular arc-shaped spacers 3 arranged in a circumferential direction, a circular ring-shaped fixing member 4, the supporting board 9, the passive element disposed on the supporting board 9, a connecting jig 6, and a multiple number of legs 7 extending from the holding member 2.

A region capable of being connected to the ground to have a ground potential is provided on the supporting board 9. Though this region can be electrically connected to the ground, it can also be set to be in a floating state. One end of the connecting jig 6 is fixed to a side surface of the supporting board 9, and the other end of the connecting jig 6 is fixed to the legs 7. Each leg 7 is made of a conductive material such as copper (Cu) or aluminum (Al), and four legs 7 are illustrated in the present exemplary embodiment. In the present exemplary embodiment, the connecting jig 6 is made of an insulator, for example, a fluorine resin (polytetrafluoroethylene (PTFE)).

The spacers 3 are placed and fixed on the holding member 2. The fixing member 4 is placed and fixed on the spacers 3. A top surface of the fixing member 4 is fixed to a bottom surface of a flange of the accommodation cover 21 of the plasma forming source 20. In the present exemplary embodiment, the accommodation cover 21 is fixed to the fixing member 4 by multiple bolts 8. The circular ring-shaped holding member 2 and the circular ring-shaped fixing member 4 are made of a conductive material such as stainless steel. In the present exemplary embodiment, the spacer 3 is made of an insulator, for example, a fluorine resin (polytetrafluoroethylene (PTFE)).

When measuring the Su as the S parameter, the accommodation cover 21 of the plasma forming source 20 is electrically connected to the ground. The reference signal a₁ is inputted to the starting point 23S of the antenna 23, and the end point 23E of the antenna 23 is electrically connected to the ground, for example (see FIG. 2). The holding member 2 and the legs 7 can be set to be in a floating state or electrically connected to the ground. The fixing member 4 is fixed to the plasma forming source 20 above it, and is electrically connected to the ground. The supporting board 9 is made of an insulator such as a resin. For example, an electrode layer for stabilization of an electric potential is disposed at a rear surface side of the supporting board 9. This electrode layer may be electrically connected to the ground or set to be in a floating state. As an example, the supporting board 9 is set to be in a floating state.

The passive element is equipped with an antenna 5, a resistor R and a capacitor C disposed on the supporting board 9. Alternatively, the passive element may be composed of the antenna 5 only. The antenna 5 may have a shape identical or of different from the shape of the antenna 23 of the plasma forming source 20. Any of the two cases is possible as long as the passive element has the antenna 5. Since the antenna 5 itself is equipped with an inductor, the passive element includes the capacitor, the inductor and the resistor. Thus, the passive element can be capacitively and inductively coupled to the plasma forming source 20.

When measuring the S₂₁ as the S parameter, the accommodation cover 21 of the plasma forming source 20 is electrically connected to the ground. The reference signal a₁ is inputted to the starting point 23S of the antenna 23, and the end point 23E of the antenna 23 is electrically connected to the second port, for example (see FIG. 3). The holding member 2 and the legs 7 can be set to be in a floating state or electrically connected to the ground. The fixing member 4 is fixed to the plasma forming source 20 above it, and is electrically connected to the ground. The supporting board 9 is made of an insulator. For example, an electrode layer for stabilization of an electric potential is disposed at a rear surface side of the supporting board 9. This electrode layer may be electrically connected to the ground to have a ground potential or set to be in a floating state. As an example, the supporting board 9 is set to be in a floating state. The antenna 5 is also set to be in a floating state.

As stated above, the load 10 includes the passive element configured to be capacitively and inductively coupled to the plasma forming source 20; the fixing member 4 configured to fix the passive element to the plasma forming source 20; and the holding member 2 for the passive element. The holding member 2 holds the passive element, and the fixing member 4 fixes the passive element to the plasma forming source 20. Thus, a position of the passive element is fixed to the plasma forming source 20, and accurate inspection can be carried out. This load 10 can be used to investigate a characteristic of the plasma forming source, as mentioned above.

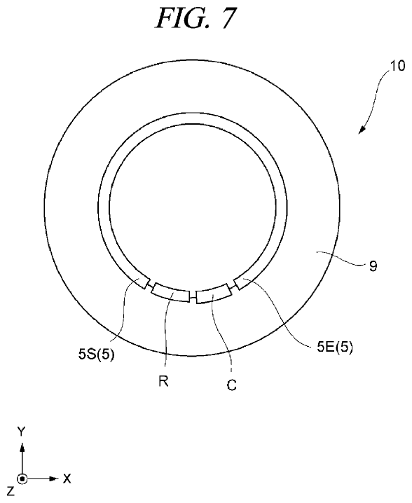

FIG. 7 is a plan view of the load 10 according to the exemplary embodiment.

The load 10 is equipped with the passive element disposed on the supporting board 9. When the passive element is composed of the antenna 5, the resistor R and the capacitor C, an RLC circuit can be built if these components are disposed in a ring shape and connected in series. Further, in FIG. 7, the antenna 5 has a circular ring shape having notched portions.

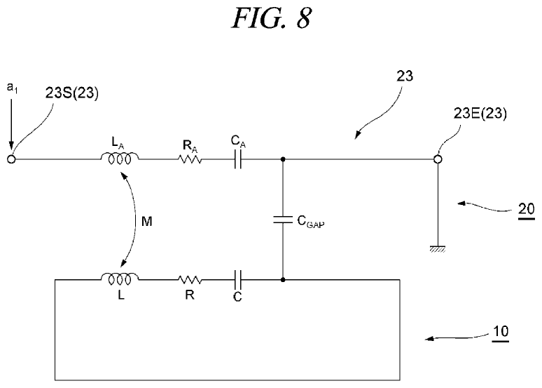

FIG. 8 is a circuit diagram illustrating an example of a coupling between the plasma forming source and the load.

If the reference signal a₁ is inputted to the starting point 23S of the antenna 23 of the plasma forming source, an electric current flows within the antenna 23 and reaches the end point 23E. Here, it is assumed that the antenna 23 has an inductor L_{A}, a resistor R_{A} and a capacitor C_{A}. Further, though the dielectric window is disposed under the plasma forming source if the apparatus is assembled, no dielectric window exists before the apparatus is assembled. Since a gap (ΔZ in FIG. 5) is provided between the antenna 23 and the passive element, there exists a capacitor C_{HAP} corresponding to this gap. AZ is set to be several centimeters. The capacitor C_{HAP} may include the dielectric window 22 made of a quartz glass or the like. In FIG. 5, a dielectric plate equivalent to the dielectric window 22 may be disposed within the load 10.

Meanwhile, the passive element may be regarded as a serial circuit of an RLC having the inductor L, the resistor R and the capacitor C, and may be considered as constructing a closed loop. The passive element is capacitively coupled to the antenna 23 via the capacitor C_{HAP} as stated above. Further, the inductor L_{A} of the antenna 23 of the plasma forming source 20 is magnetically connected to the inductor L of the load 10 below. These inductors are inductively coupled (magnetically coupled) as a mutual inductance M.

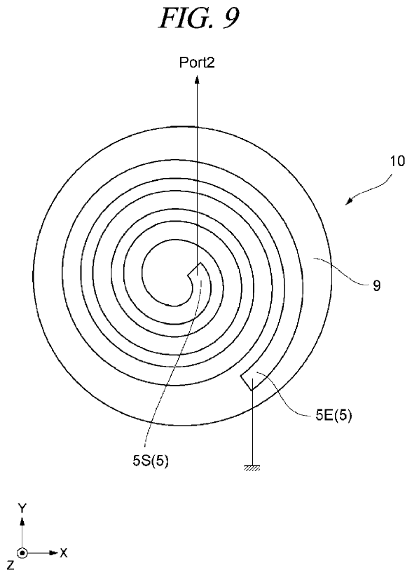

FIG. 9 is a plan view of a load according to another exemplary embodiment.

The load 10 is equipped with a passive element disposed on a supporting board 9. In the present exemplary embodiment, the passive element is composed of an antenna 5 having a spiral plan shape (a shape within an XY plane). In FIG. 9, the antenna 5 has the same shape as the antenna 23 of the plasma forming source. That is, in case that the plasma forming source 20 includes the antenna 23, the antenna 5 may have the same shape as the antenna 23.

Further, if the load 10 (a starting point 5S of the antenna 5) is electrically connected to the second port Port2, as shown in FIG. 4, an end point 5E of the antenna 5 may be electrically connected to the ground, for example. The spiral antenna may be formed to have a loop shape and electrically connected to the second port Port2. Further, as illustrated in FIG. 2 and FIG. 3, the load 10 (antenna 5) may be measured in an electrically floating state.

As stated above, the inspection method for the plasma forming source includes the process of installing the load 10 configured to be capacitively and inductively coupled to the plasma forming source 20. Further, this inspection method also includes the process of calculating the characteristic (S parameter) of the plasma forming source 20 by receiving the signal(s) b₁ and/or b₂ from the plasma forming source 20 while applying the reference signal a₁ to the plasma forming source 20.

The load 10 is a dummy load to simulate plasma ideally. Regarding an electric behavior seen from the plasma forming source 20, this load 10 is assumed to be equivalent to the plasma. If the reference signal (high frequency signal) is applied to the plasma forming source 20, the reflection signal b₁ reflected from the plasma forming source 20 and/or the transmitted signal b₂ which has passed through the plasma forming source 20 can be obtained. By receiving the signals from the plasma forming source 20, it is possible to inspect a characteristic of the plasma forming source 20 in the state the plasma is formed imaginarily.

This characteristic is the S parameter in the above-described exemplary embodiments. In this case, the plasma forming source 20 is configured to generate the reference signal and is connected with the network analyzer 41 configured to receive the signal from the plasma forming source 20. The network analyzer 41 is capable of measuring the S parameter (a parameter indicating a relationship between an input signal to the plasma forming source 20 and an output signal from the plasma forming source 20). If a S parameter of a fine-quality plasma forming source is previously measured, a quality control for an inspection target product can be carried out by measuring a S parameter of a plasma forming source as a target of inspection.

Further, the load 10 is a plasma replacement circuit and composed of a conductor, a resistor, a capacitor and a coil as circuit elements. The plasma forming source may be equipped with an antenna for inductively coupled plasma (ICP). By installing the load 10 to a fixed position when viewed from this antenna, a geometric relationship between the plasma forming source 20 and the load 10 (plasma) and a characteristic of the plasma can be maintained constant. Accordingly, pure information of the plasma forming source can be obtained, and the S parameter of the plasma forming source can be measured and compared accurately.

To elaborate, according to the above-described method, the S parameter as a combination of the plasma forming source and the plasma can be measured from the outside to compare performance of the plasma forming source and an inter-apparatus characteristic difference. Conventionally, in the art, a frequency characteristic of synthetic S parameter cannot be measured in the middle of application of a high frequency (RF) power. That is, to measure the S parameter by using a measurer such as a network analyzer in the middle of the application of the RF power, a method of calculating the aforementioned combined impedance from information of a voltage and a current of the applied power in formation of plasma has been taken into account. In this case, however, if there is a difference in the characteristic of the plasma forming source, the plasma itself is changed, and the plasma cannot be maintained constant. As a result, a pure characteristic difference of each pure plasma forming source cannot be extracted.

Further, in the reality, a shape of the plasma changes, so that a positional relationship with respect to a plasma source is also changed. As a result, the combined S parameter fluctuates. Even if the S parameter is measured only with the single plasma forming source, a characteristic difference of each apparatus cannot be obtained. Thus, in the above-described exemplary embodiments, a circuit composed of such elements as a conductor and a resistor is mounted to a measurement system as an imitation of plasma which is maintained constant. According to this method, it is possible to measure the S parameter of the plasma forming source in consideration of a geometric relationship with respect to the plasma and a plasma characteristic.

According to the above-described method, to imitate, without forming plasma actually, a state in which the plasma is formed, the S parameter is measured by using the measurer such as the network analyzer in the state that the circuit as the imitation of the plasma is placed at the fixed position when viewed from the plasma forming source. A shape and a circuit configuration of the passive element can be modified as required. Further, a connecting component such as a coaxial connector to be connected to the outside may be connected to the antenna if it is required for the measurement of the S₂₁ (passing characteristic) or the like. Further, in the load 10, the positional relationship with respect to the plasma forming source 20 and pseudo-plasma characteristic can be changed as required. Thus, a type of connection (capacitive coupling/inductive coupling) between the plasma forming source and the mock plasma (load 10) can be set as required without being delimited. Furthermore, an inspection can be performed only if the plasma forming source, the load 10 (a supplementary measurement tool) and the measurer such as the network analyzer are provided. Thus, it is possible to measure the S parameter which is the imitation of the state in which these components are actually mounted to a semiconductor manufacturing apparatus without actually mounting them to the semiconductor manufacturing apparatus. Moreover, if the measurer such as the network analyzer is used, a parameter, such as an impedance, other than the S parameter can also be measured.

In addition, in the above-described exemplary embodiments, the network analyzer and the ground are respectively connected to the two opposite ends (staring point/end point) of the antenna 23 (coil). Connection points between the network analyzer and the antenna 23 (coil), however, are not limited to the starting point and the end point, and may be set to be any two positions on the coil. The same connection scheme may be adopted for the antenna 5.

According to the exemplary embodiment, it is possible to provide the inspection method capable of carrying out inspection of the characteristic of the plasma forming source, and, also, provide the load therefor.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting. The scope of the inventive concept is defined by the following claims and their equivalents rather than by the detailed description of the exemplary embodiments. It shall be understood that all modifications and embodiments conceived from the meaning and scope of the claims and their equivalents are included in the scope of the inventive concept.

We claim:

1. An inspection method of a plasma forming source, comprising:
providing a load configured to be capacitively and inductively coupled to the plasma forming source; and
calculating a characteristic of the plasma forming source by receiving a signal from the plasma forming source while sending a reference signal to the plasma forming source.

2. The inspection method of the plasma forming source of claim 1,
wherein the load comprises:
a passive element configured to be capacitively and inductively coupled to the plasma forming source;
a fixing member configured to fix the passive element to the plasma forming source; and
a holding member configured to hold the passive element.

3. The inspection method of the plasma forming source of claim 2,
wherein the passive element comprises an antenna.

4. The inspection method of the plasma forming source of claim 1,
wherein the characteristic is a S parameter, and
the plasma forming source is connected to a network analyzer configured to generate the reference signal and receive the signal from the plasma forming source.

5. A load, comprising:
a passive element configured to be capacitively and inductively coupled to a plasma forming source;
a fixing member configured to fix the passive element to the plasma forming source; and
a holding member configured to hold the passive element.

6. The load of claim 5,
wherein the passive element comprises an antenna.
